(19) United States
(12) Patent Application Publication
(10) Pub. No.: US 2026/0262164 A1
(43) Pub. Date: Sep. 3, 2026

(54) PCB SIGNAL VIA STRUCTURE AND DETERMINATION METHOD, DETERMINATION APPARATUS, AND DETERMINATION DEVICE FOR PCB SIGNAL VIA STRUCTURE

(71) Applicant: SUZHOU METABRAIN INTELLIGENT TECHNOLOGY CO., LTD., Suzhou, Jiangsu (CN)

(72) Inventor: Yajun LI, Suzhou, Jiangsu (CN)

(21) Appl. No.: 18/718,385

(22) PCT Filed: Sep. 27, 2022
(86) PCT No.: PCT/CN2022/121929

§ 371 Date: Jun. 10, 2024

(30) Foreign Application Priority Data
Apr. 27, 2022 (CN) 202210453033.6

(51) Int. Cl. H05K 1/11; H05K 3/00

(52) U.S. Cl. CPC H05K 1/115; H05K 3/0005; H05K 2201/09509; H05K 2201/09536; H05K 2201/09545

(57) ABSTRACT

PCB signal via structure, a determination method, determination apparatus, and determination device for a PCB signal via structure, and a computer-readable storage medium are disclosed. During design of layer switching vias for signals on a PCB, an existing design mode in which one hole is punched for one signal that needs to switch layers is changed. Vias are punched in a collective manner for a plurality of signals that need to switch layers; and in-via routes for the various signals that need to switch layers are arranged on an inner wall of the via structure, and the in-via routes are insulated from each other, so that the problem that the continuity of impedance at the layer switching vias for the signals is hard to control is solved, and there is no need to conduct an anti-pad design, thereby solving the problem of the layer switching vias occupying a large space.

### CROSS-REFERENCE TO RELATED APPLICATION

This application claims priority to Chinese Patent Application No. 202210453033.6, entitled “PCB SIGNAL VIA STRUCTURE AND DETERMINATION METHOD, DETERMINATION APPARATUS, AND DETERMINATION DEVICE FOR PCB SIGNAL VIA STRUCTURE” filed with the China National Intellectual Property Administration on Apr. 27, 2022, which is incorporated herein by reference in its entirety.

### FIELD

The present application relates to the technical field of printed circuit boards (PCBs), and in particular, to a PCB signal via structure and a determination method, determination apparatus, and determination device for a PCB signal via structure, and a computer-readable storage medium.

### BACKGROUND

With the development of an electronic information technology and continuous increase of a signal transmission rate, people have put forward a higher requirement for signal performance. Therefore, in a research and development process, R&D designers need to more finely consider and handle many problems in a printed circuit board (hereinafter referred to as PCB) design process, so as to achieve cost minimization based on performance optimization.

FIG. 1 is a schematic diagram of signal line layer switching and punching in an existing technology.

In an existing PCB design, during layer switching design for a signal line based on vias, the punching mode shown in FIG. 1 is usually used, that is, on a PCB 101, a circular via 102 is arranged for each signal that needs to switch layers. A differential signal is taken as an example, it is necessary to add a ground (GND) reflow hole (referred to as a ground hole) around a DP and a DN of the differential signal. A center distance between the DP hole and the DN hole is generally 40 mils (length unit: mils) or 32 mils, and a center distance between each of the DP hole and DN hole and the ground hole beside is also generally 40 mils.

It can be seen that the existing mode for designing layer switching for a signal line based on vias occupies a relatively large space of the PCB, which is not conducive to reducing the design cost of a product. The circular via is different from a route, and the impedance of a signal cannot be controlled at the via. As a result, the impedance of a signal at a layer switching place and the impedance of the signal at a route portion on a PCB layer are discontinuous. In order to ensure the impedance continuity of a signal line at the layer switching place, an additional anti-pad design needs to be added (that is, a copper surface is dug out outside a periphery of a circular pad of the via), which brings a great load to PCB designers. Moreover, a plating through hole design may often leave a large number of stubs (which means that during punching of plating through holes on a multilayer PCB to allow a signal line to pass through the plating through holes for layer switching, places, where the signal line does not pass through, in the plating through holes are stubs), causing signal line integrity issues. Adding an additional back drilling process can reduce the stubs to 10 miles, which is not conducive to reducing production costs and reducing signal reflection.

Providing a layer switching solution for a signal line based on vias that saves the space of the PCB is a technical problem that those skilled in the art need to solve.

### SUMMARY

The present application provides a PCB signal via structure, including a via structure arranged on a PCB and in-via routes arranged on an inner wall of the via structure,
wherein the via structure spans from a signal starting layer of signals that need to switch layers in the PCB to a signal destination layer of the signals that need to switch layers; the in-via routes are in one-to-one correspondence to the signals that need to switch layers to serve as via links of the signals that need to switch layers; and the various in-via routes are insulated from each other.

In one or more embodiments, each in-via route is specifically obtained by performing groove milling on the copper surface according to a line width of each signal that needs to switch layers and a line distance of each signal that needs to switch layers after the via structure is obtained from the PCB and the inner wall of the via structure is electroplated with a copper surface that has the same thickness as a layer surface of the PCB.

In one or more embodiments, the via structure includes a plating through hole structure; and
the plating through hole structure penetrates through the PCB.

In one or more embodiments, the via structure includes a blind via hole structure; and
the blind via hole structure spans from a surface layer to an inner layer of the PCB and does not penetrate through the PCB.

In one or more embodiments, the via structure includes a buried via hole structure; and
the buried via hole structure spans from an inner layer of the PCB, and plating flattening treatment is performed on one side of a surface close to the PCB.

In one or more embodiments, a cross section of the via structure is specifically shaped like a Chinese character “-”.

In one or more embodiments, a cross section of the via structure is specifically a cross.

In one or more embodiments, a cross section of the via structure is specifically L-shaped.

In one or more embodiments, each signal that needs to switch layers is a differential signal;
the via structure at least includes a first via structure; and
a pair of differential signals in the first via structure is only provided with ground signals on two sides.

In one or more embodiments, each signal that needs to switch layers is a differential signal;
the via structure at least includes a second via structure; and
a pair of differential signals in the second via structure is provided with ground signals on two sides and opposite sides.

The present application further provides a PCB, including any one of the PCB signal via structures described above.

The present application further provides a determination method for a PCB signal via structure, including:
obtaining information of signals that need to switch layers on a PCB, wherein the information of the signals that need to switch layers at least includes a signal starting layer of the signals that need to switch layers and a signal destination layer of the signals that need to switch layers; and
determining a position and shape of the PCB signal via structure on the PCB according to the information of a plurality of signals that need to switch layers,
wherein the PCB signal via structure includes a via structure arranged on the PCB and in-via routes arranged on an inner wall of the via structure; the via structure spans from the signal starting layer of the signals that need to switch layers in the PCB to the signal destination layer of the signals that need to switch layers; the in-via routes are in one-to-one correspondence to the signals that need to switch layers to serve as via links of the signals that need to switch layers; and the various in-via routes are insulated from each other.

In one or more embodiments, the determining a position and shape of the PCB signal via structure on the PCB according to the information of a plurality of signals that need to switch layers specifically includes:
classifying the plurality of signals that need to switch layers into a group of signals that need to switch layers according to an inter-signal spatial distance; and
determining the position and shape of the PCB signal via structure corresponding to the group of signals that need to switch layers according to the information of the various signals that need to switch layers in the group of signals that need to switch layers.

In one or more embodiments, the determining a position and shape of the PCB signal via structure on the PCB according to the information of a plurality of signals that need to switch layers specifically includes:
classifying the plurality of signals that need to switch layers into a group of signals that need to switch layers according to a signal type; and
determining the position and shape of the PCB signal via structure corresponding to the group of signals that need to switch layers according to the information of the various signals that need to switch layers in the group of signals that need to switch layers.

In one or more embodiments, the determining a position and shape of the PCB signal via structure on the PCB according to the information of a plurality of signals that need to switch layers specifically includes:
classifying the plurality of signals that need to switch layers into a group of signals that need to switch layers according to an inter-signal spatial distance and a signal type; and
determining the position and shape of the PCB signal via structure corresponding to the group of signals that need to switch layers according to the information of the various signals that need to switch layers in the group of signals that need to switch layers.

In one or more embodiments, the via structure at least includes at least one of a plating through hole structure, a blind via hole structure, and a buried via hole structure,
wherein the plating through hole structure penetrates through the PCB; the blind via hole structure spans from a surface layer to an inner layer of the PCB and does not penetrate through the PCB; and the buried via hole structure spans from an inner layer of the PCB, and plating flattening treatment is performed on one side of a surface close to the PCB.

In one or more embodiments, each signal that needs to switch layers is a differential signal;
the via structure at least includes at least one of a first via structure and a second via structure;
a pair of differential signals in the first via structure is only provided with ground signals on two sides; and a pair of differential signals in the second via structure is provided with the ground signals on two sides and opposite sides.

The present application further provides a determination apparatus for a PCB signal via structure, including:
an obtaining unit, configured for obtaining information of signals that need to switch layers on a PCB, wherein the information of the signals that need to switch layers at least includes a signal starting layer of the signals that need to switch layers and a signal destination layer of the signals that need to switch layers; and
a determination unit, configured for determining a position and shape of the PCB signal via structure on the PCB according to the information of a plurality of signals that need to switch layers,
wherein the PCB signal via structure includes a via structure arranged on the PCB and in-via routes arranged on an inner wall of the via structure; the via structure spans from the signal starting layer of the signals that need to switch layers in the PCB to the signal destination layer of the signals that need to switch layers; the in-via routes are in one-to-one correspondence to the signals that need to switch layers to serve as via links of the signals that need to switch layers; and the various in-via routes are insulated from each other.

The present application further provides a determination device for a PCB signal via structure, including a memory and one or more processors, wherein the memory stores computer-readable instructions; and the computer-readable instructions, when executed by the one or more processors, cause the one or more processors to perform the steps of any one of the methods described above.

The present application further provides one or more non-volatile computer-readable storage media storing computer-readable instructions, wherein the computer-readable instructions, when executed by one or more processors, cause the one or more processors to perform the steps of any one of the methods described above.

### BRIEF DESCRIPTION OF THE DRAWINGS

To describe the technical solutions in the embodiments of the present application or in the related art more clearly, the following briefly introduces the accompanying drawings for describing the embodiments or the related art. Apparently, the accompanying drawings in the following description show merely some embodiments of the present application, and a person of ordinary skill in the art may still derive other drawings from the accompanying drawings without creative efforts.

FIG. 1 is a schematic diagram of signal line layer switching and punching in an existing technology;

FIG. 2 is a schematic structural diagram of a first kind of PCB signal via structure according to one or more embodiments of the present application;

FIG. 3 is a top view of a first kind of PCB signal via structure according to one or more embodiments of the present application;

FIG. 4 is a schematic diagram of comparison between a PCB signal via structure and an existing PCB signal via structure according to one or more embodiments of the present application;

FIG. 5 is a partially enlarged diagram of FIG. 4;

FIG. 6 is a schematic diagram of a first processing mode according to one or more embodiments of the present application;

FIG. 7 is a top view of a second kind of PCB signal via structure according to one or more embodiments of the present application;

FIG. 8 is a top view of a third kind of PCB signal via structure according to one or more embodiments of the present application;

FIG. 9 is a schematic diagram of a second processing mode according to one or more embodiments of the present application;

FIG. 10 is a top view of a fourth kind of PCB signal via structure according to one or more embodiments of the present application;

FIG. 11 is a schematic diagram of a third processing mode according to one or more embodiments of the present application;

FIG. 12 is a top view of a fifth kind of PCB signal via structure according to one or more embodiments of the present application;

FIG. 13 is a schematic diagram of a fourth processing mode according to one or more embodiments of the present application;

FIG. 14 is a schematic diagram of a signal path of a blind via hole structure according to one or more embodiments of the present application;

FIG. 15 is a cross-sectional diagram of a step-like blind via hole according to one or more embodiments of the present application;

FIG. 16 is a schematic diagram of a processing mode of a buried via hole structure according to one or more embodiments of the present application;

FIG. 17 is a flowchart of a determination method for a PCB signal via structure according to one or more embodiments of the present application;

FIG. 18 is a schematic structural diagram of a determination apparatus for a PCB signal via structure according to one or more embodiments of the present application; and

FIG. 19 is a schematic structural diagram of a determination device for a PCB signal via structure according to one or more embodiments of the present application.

101: PCB; 102: circular via; 100: existing PCB signal via structure;
201: PCB; 202: via structure; 203: in-via route; 200: PCB signal via structure according to one or more embodiments of the present application.

### DETAILED DESCRIPTION

The core of the present application is to provide a PCB signal via structure and a determination method, determination apparatus, and determination device therefor, and a computer-readable storage medium, to solve the problems of poor impedance continuity and a large occupied space of existing PCB signal vias.

The technical solutions in embodiments of the present application are clearly and completely described in the following with reference to the accompanying drawings in the embodiments of the present application. Apparently, the described embodiments are merely some rather than all of the embodiments of the present application. All other embodiments obtained by a person of ordinary skill in the art based on the embodiments of the present application without making creative efforts shall fall within the protection scope of the present application.

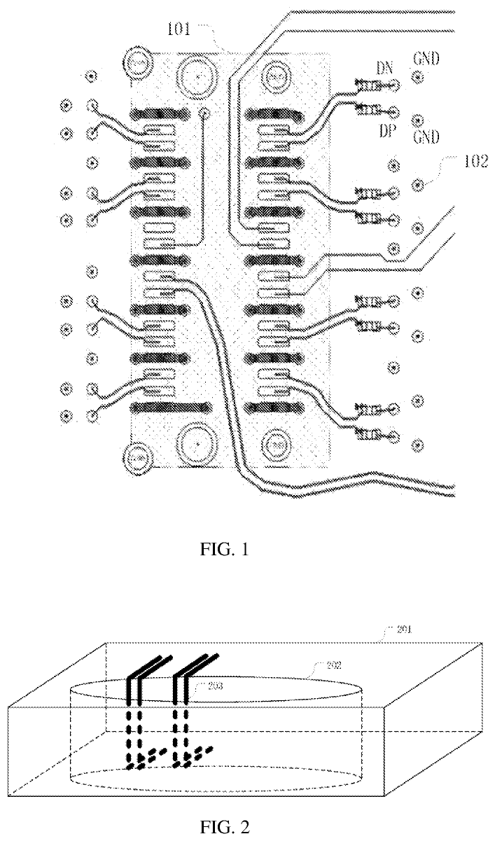

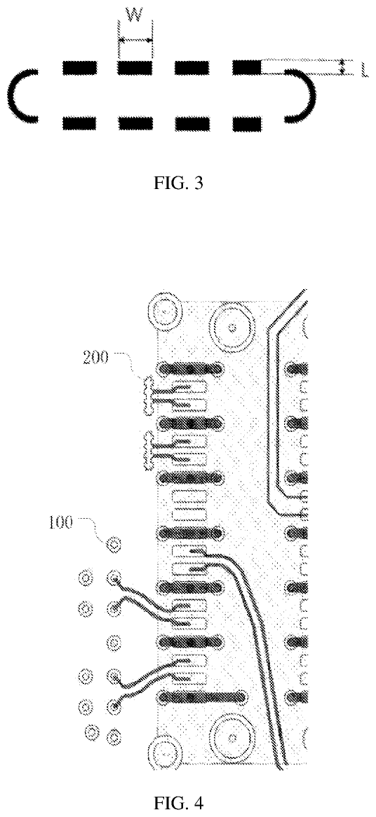

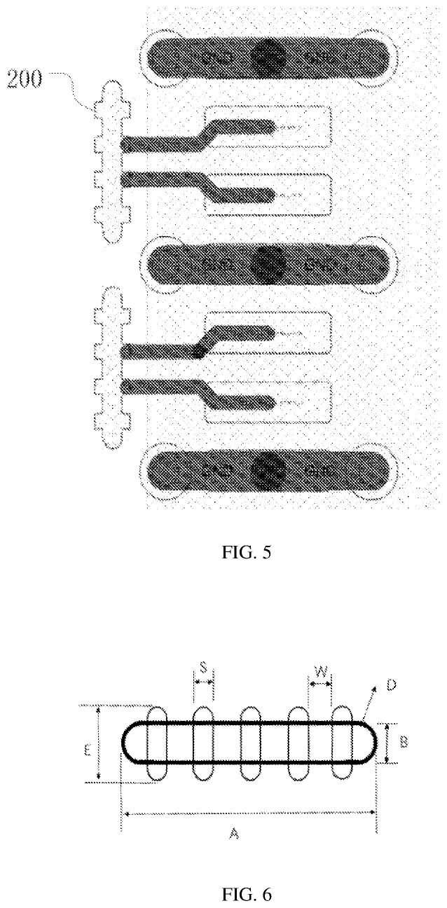

In some embodiments of the present application, FIG. 2 is a schematic structural diagram of a first kind of PCB signal via structure according to an embodiment of the present application; FIG. 3 is a top view of a first kind of PCB signal via structure according to an embodiment of the present application; FIG. 4 is a schematic diagram of comparison between a PCB signal via structure and an existing PCB signal via structure according to an embodiment of the present application; and FIG. 5 is a partially enlarged view of FIG. 4.

As shown in FIG. 2, a PCB signal via structure provided by the embodiments of the present application includes a via structure 202 arranged on a PCB 201 and in-via routes 203 arranged on an inner wall of the via structure 202,
wherein the via structure 202 spans from a signal starting layer of signals that need to switch layers in the PCB 201 to a signal destination layer of the signals that need to switch layers; the in-via routes 203 are in one-to-one correspondence to the signals that need to switch layers to serve as via links of the signals that need to switch layers; and the various in-via routes 203 are insulated from each other.

In the existing technology, during PCB signal via layer switching, one hole needs to be punched for each signal that needs to switch layers, and copper is laid on an inner wall of the via to form a via link for the signal that needs to switch layers. As the via link is composed of a copper surface fully covering the inner wall of the via, it is hard to keep continuous impedance for a route of the signal that needs to switch layers on a layer surface. Therefore, an anti-pad design needs to be conducted on a circular pad of the via. This not only occupies a large area and brings tedious work for a PCB designer, but also causes very high processing costs in the design of blind via holes and buried via holes.

For this problem, the embodiments of the present application provide a novel PCB signal via structure. Via links of a plurality of signals that need to switch layers are designed in one via structure 202. That is, after one via structure 202 is punched for the plurality of signals that need to switch layers, in-via routes 203 of the various signals that need to switch layers are processed on an inner wall of the via structure 202, thus forming the via links of the various signals that need to switch layers.

Based on the design concept of the PCB signal via structure provided by the embodiments of the present application, designing via links for the various signals that need to switch layers can better achieve customized processing, whereby the impedance of the via links for the signals that need to switch layers is consistent with the impedance of surface-layer routes of the signals that need to switch layers, thereby solving the problem that the via impedance cannot be controlled in a current circular via technology. As shown in FIG. 3, in the design concept of the PCB signal via structure provided in the embodiments of the present application, a cross section of the via structure 202 may be oblong, and the via structure 202 reduces the requirement for the processing accuracy compared with a via for a single signal. Furthermore, compared with a circular pad of an existing circuit via, a pad of each via link in the embodiments of the present application may be processed into a square structure. A length W of the square pad may be designed to be equal to a width of a surface-layer route of the signal that needs to switch layers. A thickness of the square pad may be designed to be equal to a thickness of a layer surface of the signal that needs to switch layers. A width L of the square pad may be designed to be a value (such as 12 miles) that is convenient for processing, thereby eliminating the problem that the impedance of the in-via routes 203 and the impedance of the surface-layer route are discontinuous and eliminating the need to dig an anti-pad in an inner layer. This greatly simplifies the design of the PCB and avoids the limitation (cross segmentation problem) caused by a large anti-pad on a middle-layer route.

Due to a design requirement for a distance between signals, a distance between the in-via routes 203 should not be less than a distance between the surface-layer route of the signals that need to switch layers. Meanwhile, to ensure the optimal space utilization rate, the distance between the in-via routes 203 should be consistent with the distance between the surface-layer routes.

The insulation design between the in-via routes 203 may be achieved by filling the via structures 202 with an insulation material using a via filling process after the processing of the in-via routes 203 is completed. Specifically, a resin material may be used for via filling.

The signals that need to switch layers of the PCB signal via structure provided in the embodiments of the present application include but are not limited to high-speed differential lines, high-speed signals at golden fingers, high-speed signals at other devices, and low-speed signals with dense layer switching holes, thereby transforming traditional vias into the in-via routes 203, greatly reducing the distance between the signals that need to switch layers and saving a space for PCB design. A distance from a high-speed signal output pin to the via structure 202 may be designed to be shorter, thereby reducing the length of the surface-layer route. As shown in FIG. 4 and FIG. 5, it can be seen that the distance between the PCB signal via structure 200 provided by the embodiments of the present application and a signal pin may be designed to be much less than the distance between the existing PCB signal via structure 100 and a signal pin, and can meet a shielding requirement between signals and an impedance control requirement.

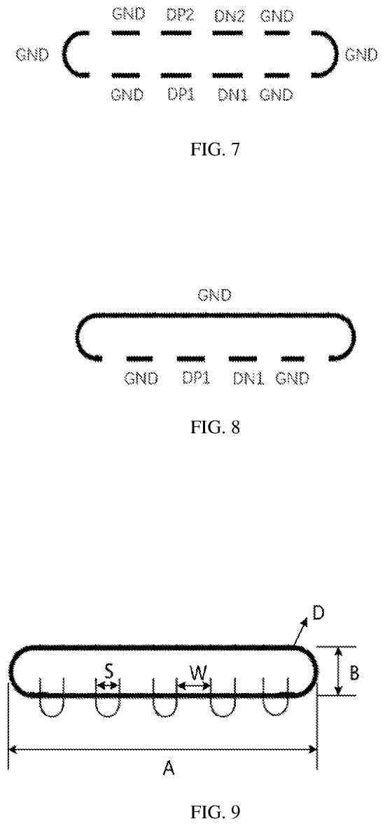

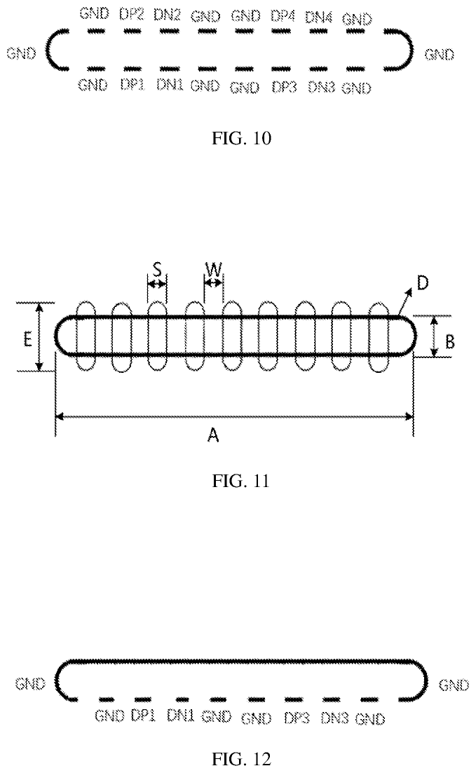

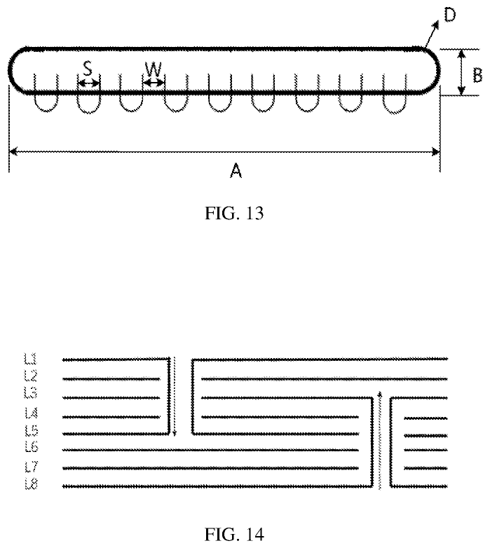

In some embodiments of the present application, FIG. 6 is a schematic diagram of a first processing mode according to the embodiments of the present application; FIG. 7 is a top view of a second kind of PCB signal via structure according to the embodiments of the present application; FIG. 8 is a top view of a third kind of PCB signal via structure according to the embodiments of the present application; FIG. 9 is a schematic diagram of a second processing mode according to the embodiments of the present application; FIG. 10 is a top view of a fourth kind of PCB signal via structure according to the embodiments of the present application; FIG. 11 is a schematic diagram of a third processing mode according to the embodiments of the present application; FIG. 12 is a top view of a fifth kind of PCB signal via structure according to the embodiments of the present application; and FIG. 13 is a schematic diagram of a fourth processing mode according to the embodiments of the present application.

Based on the above embodiments, in the PCB signal via structure provided in the embodiments of the present application, each in-via route 203 is specifically obtained by performing groove milling on the copper surface according to a line width of each signal that needs to switch layers and a line distance of each signal that needs to switch layers after the via structure 202 is obtained from the PCB 201 and the inner wall of the via structure 202 is electroplated with a copper surface that has the same thickness as a layer surface of the PCB 201.

Referring to FIG. 6, for the PCB signal via structure as shown in FIG. 3, during the processing design, a via structure 202 may be milled using a milling cutter, specifically, a via structure 202 as shown in FIG. 6, which has an oblong cross section with a length of A and a width of B, and has a depth of C. Values of A and B may be flexibly adjusted according to a design requirement and processing requirement of the PCB 201. The depth C is determined by a layer switching requirement (signal starting layer and signal destination layer) of the signal that needs to switch layers, or is direct a thickness of the PCB 201.

Afterwards, the inner wall of the via structure 202 is electroplated with the copper surface with a thickness of D (D may be 1.2 mils) is electroplated on. The thickness of the electroplated copper should be the same as a thickness of an inner-layer copper foil, whereby it is convenient to control the impedance of the in-via route 203.

After the electroplating of copper is completed, secondary groove milling needs to be performed. A secondarily milled groove has a length of E, a width of S, and a depth of C. A distance between two adjacent secondarily milled grooves is W, which means that after a portion that does not require copper foil connection is milled off, a width of a remaining unmilled copper foil is W, to serve as the in-via route 203. A value of W may be a line width of a high-speed signal.

After the secondary groove milling, via filling is performed on the via structure 202.

In addition, other modes may be used to process the in-via route 203, such as a mode for directly laying the in-via route 203 on the inner wall of the via.

For a differential signal, it is usually necessary to set ground signals around a pair of differential signals DP and DN to achieve signal isolation. As shown in FIG. 1, in the existing technology, two additional ground holes or four vias need to be designed for a via of each pair of differential signals according to the shielding requirement. Therefore, each pair of differential signals requires four or six vias, and each via needs to be designed with an anti-pad, which occupies a large space.

During implementation of a via of differential signals based on the PCB signal via structure as shown in FIG. 3, a signal distribution mode as shown in FIG. 7 may be designed. FIG. 7 may be processed using the mode as shown in FIG. 6. As shown in FIG. 7, two pairs of differential signals DP1, DN1, DP2, and DN2 may be designed, and ground signals may be set on two sides of each pair of differential signals. Via routes at corners may be directly set to be the ground signals.

When a differential signal has a higher signal shielding requirement, as shown in FIG. 1, ground holes need to be set around a via of the differential signal for isolation.

Based on the above embodiments, in the PCB signal via structure provided by the embodiments of the present application, each signal that needs to switch layers is a differential signal; the via structure 202 at least includes at least one of a first via structure and a second via structure; and a pair of differential signals in the first via structure is only provided with ground signals on two sides; and a pair of differential signals in the second via structure is provided with the ground signals on two sides and opposite sides.

As shown in FIG. 8, in-via routes 203 of the differential signals may be set only on one side of the via structure 202, and the other side serves as a ground signal. The structure as shown in FIG. 8 may be as shown in FIG. 9 during processing. Only the copper surface in the via on a single side is milled off during the secondary groove milling. The PCB signal via structure shown in FIG. 8 only includes a pair of differential signals DP1 and DN1.

It should be noted that the first via structure in the embodiments of the present application includes but is not limited to the structures shown in FIG. 3 and FIG. 7, and the second via structure includes but is not limited to the structure shown in FIG. 8. When a PCB signal via structure includes two differential signals with different signal shielding requirements, two different in-via routes 203 may be simultaneously designed in a via structure 202, that is, a via structure 202 includes both the first via structure and the second via structure.

For the first via structure, the PCB signal via structure shown in FIG. 7 includes two pairs of differential signals. Based on this, as shown in FIG. 10, the PCB signal via structure includes four pairs of differential signals DP1, DN1, DP2, DN2, DP3, DN3, DP4, and DN4. Each pair of differential signals are provided with in-via routes 203 of two ground signals on two sides, and an edge of the inner wall of the via structure 202 is also designed to be an in-via route 203 of a ground signal. The processing mode of FIG. 10 is shown in FIG. 11, which may refer to the explanation of FIG. 6 for details.

Similarly, for the second via structure, based on the PCB via structure including a pair of differential signals shown in FIG. 8, it may be derived to the second via structure including two pairs of differential signals DP1, DN1, DP3, and DN3 shown in FIG. 12. The processing mode of FIG. 12 is shown in FIG. 13, which may refer to the explanation of FIG. 9 for details.

Based on FIG. 7 and FIG. 9, further, a PCB signal via structure may include six pairs, eight pairs, . . . of differential signals. Based on FIG. 8 and FIG. 12, there may be schemes including three pairs and four pairs of differential signals.

When a via structure 202 includes both a first via structure and a second via structure, as shown in FIG. 10, if the differential signals DP3 and DN3 are signals with higher shielding requirements, DP4 and DN4 may be replaced with in-via routes 203 of ground signals, and the remaining differential signals remain unchanged.

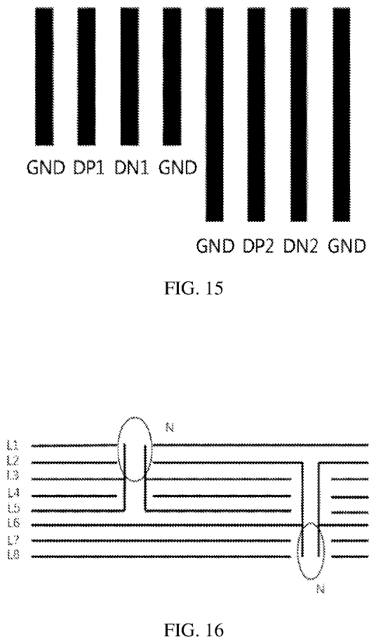

In some embodiments of the present application, FIG. 14 is a schematic diagram of a signal path of a blind via hole structure according to the embodiments of the present application; FIG. 15 is a cross-sectional diagram of a step-like blind via hole according to the embodiments of the present application; and FIG. 16 is a schematic diagram of a processing mode of a buried via hole structure according to the embodiments of the present application.

Existing PCB vias may usually be classified into three structures according to depths of the vias: a Plating Through Hole (PTH), a Blind Via Hole (BVH), and a Buried Via Hole (BVH).

The plating through hole penetrates through all layers of the PCB, which is a type of PCB via processed by the simplest processing mode. Only a mechanical drill or laser is used to fully drill the PCB, and the processing cost is low. However, when a signal that needs to switch layers has a requirement for layer switching not from a top layer to a bottom layer, some circuit layers do not need to be connected to the plating through hole, resulting in a waste of a route space of the PCB.

The blind via hole spans a surface layer of the PCB to an inner layer of the PCB, but does not penetrate through the PCB, which is to increase the utilization rate of the space of the PCB. A processing mode for the blind via holes requires a drilling depth to be just right, and has an extremely high requirement for the precision of a via caliber, whereby laser drilling with high cost needs to be used. Or, a laser drilling and lamination technology may be used. Lamination is performed layer by layer from an inner circuit layer once every time one layer is drilled. This also requires a relatively precise positioning and alignment device. It is hard to perform in-via electroplating on the blind via hole. Furthermore, this lamination process may not use a low-cost mechanical punching mode. The blind via hole is rarely used because of high processing difficulty and high processing cost.

The buried via hole is connected to any circuit layer in the PCB, but is not led to an outer layer. Compared with the blind via hole, the buried via hole needs to be processed more precisely and is difficultly obtained directly on a multilayer PCB. Therefore, it is necessary to fully drill some circuit layers and then bond the various circuit layers into a multilayer PCB. Its processing cost is the highest.

It can be seen that in addition to the discontinuity of the impedance and the large occupied space, the PCB via design mode of the existing technology that one hole needs to be punched for one signal that needs to switch layers greatly increases the processing cost of processing of blind via holes and buried via holes, and is hard to implement.

Based on the concept of the PCB signal via structure provided in Embodiment I of the present application, via links of a plurality of signals that need to switch layers are designed in one via structure 202. The requirement for the processing precision of the via structure 202 is greatly lowered compared with the existing technology. Therefore, the via structure 202 may be designed to be a plating through hole structure, and the blind via hole structure and the buried via hole structure may be achieved at low costs.

In the PCB signal via structure provided in the embodiments of the present application, a via structure 202 at least includes at least one of a plating through hole structure, a blind via hole structure, and a buried via hole structure.

The plating through hole structure penetrates through the PCB 201; the blind via hole structure spans from a surface layer to an inner layer of the PCB 201 and does not penetrate through the PCB 201; and the buried via hole structure spans from an inner layer of the PCB 201, and plating flattening treatment is performed on one side of a surface close to the PCB 201.

The blind via hole structure provided in the embodiments of the present application may also be referred to as a blind groove structure. By controlling a depth of the via structure 202, a signal that needs to switch layers may directionally switch to the inner layer of the PCB 201, without any stub. As shown in FIG. 14, a multilayer PCB is punched from a surface layer (a top layer or a bottom layer) of the PCB towards the inside to form a blind via hole (a blind groove). As the via structure 202 provided in the embodiments of the present application has a larger caliber compared with the existing circular via, blind via hole processing using laser drilling and multi-lamination technology is not required. The technology is simple and the cost is low. With the current processing capacity of a PCB factory, this via structure is easily achieved in a large batch. Moreover, the introduction of the blind via hole structure saves the space for wiring of the PCB 201, making it easier to fully use the design space of the PCB 201 and reduce route layers, thereby reducing the design and production costs of the product.

In an eight-layer PCB as shown in FIG. 14, blind via holes may be punched from the top layer and bottom layers of the PCB for a signal that needs to switch layers from layer L1 to layer L5 and a signal that needs to switch layers from layer L8 to layer L3. A processing mode provided in Embodiment II of this application can also be specifically used. First, a punching depth C is controlled to obtain a blind via hole structure, and then secondary groove milling is performed to meet a layer switching requirement of a signal that needs to switch layers from a surface layer to any inner layer of the PCB.

In the design of the PCB, adjacent signals that need to switch layers sometimes need to go to different inner layers. If via links of these adjacent signals that need to switch layers are arranged in a via structure 202, a depth of the deepest inner layer may be the depth C of the via structure 202. To save the route space of the PCB, the blind via hole structure may be set to be a step-like blind via hole structure. As shown in FIG. 15, assuming that differential pairs DP1, DN1 and their ground holes, and differential pairs of DP2, DN2 and their ground holes need to go to different inner layers, blind via hole structures of the same via structure 202 may be set to be blind via holes with different depths, thus forming a step-like blind via hole (step-like blind groove) seen from a side section of the PCB 201.

Furthermore, the blind via holes may only achieve switching a signal that needs to switch layers from the surface layer to the inner layer, without stubs. To avoid stubs during switching of a signal that needs to switch layers from an inner layer to an inner layer, stubs from the surface layer to the inner layer need to be removed based on the blind via holes. Based on the concept of the PCB signal via structure provided in Embodiment I of the present application, a more cost-effective buried via hole design that saves the route space of the PCB can be achieved, that is, the buried via hole structure described in the embodiments of the present application.

Specifically, blind via holes may be started to be processed on one, closer to the surface layer, of the signal starting layer and the signal destination layer of the signal that needs to switch layers. After the processing of the in-via routes 203 is completed (for example, after the secondary groove milling of the processing mode provided in Embodiment II of the present application), one side of an opening of each blind via hole is back-drilled to remove the stubs from the surface layer to the inner layer. As shown in FIG. 16, N represents the stubs that need to be removed by back drilling. After the stubs of the buried via holes are removed by back drilling, the original positions of the stubs may be filled (such as, with resin).

In this way, the buried via hole design can be achieved without introducing the laser drilling and the multi-lamination technology. The process is simple and easy to implement, has low cost, and has a wider application scenario in the server industry.

After the buried via holes are filled, plating flattening can be performed on surfaces of punched positions of a punched layer, whereby this region can be continued to be routed, thereby improving the space utilization rate of the PCB 201, reducing route layers, reducing the cost of the product, and improving the competitiveness of the product.

In practical applications, for a plurality of signals that need to switch layers, to design via links in a via structure 202, the entire via structure 202 is processed into one of a plating through hole structure, a blind via hole structure, or a buried via hole structure according to layer switching requirements of the signals that need to switch layers, or different digging depths are set in the via structure 202, or filling treatment is performed in the via structure 202, whereby the via structure 202 may include two to three structures of the plating through hole structure, the blind via hole structure, or the buried via hole structure. The blind via hole structure may further include a step-like blind via hole.

In some embodiments of the present application, Embodiment III above introduces three types of via structures 202 that can be included in the PCB signal via structure provided in the present application from the shape of a longitudinal section. In addition, in the above embodiments, as shown in FIG. 2 to FIG. 13, the via structures 202 are all via structures with a cross section shaped like a Chinese character “-” (oblong). In practical applications, the present application may not be limited to this cross section shape, that is, in the PCB signal via structure provided in the present application, the cross section of the via structure 202 may be shaped like a Chinese character “-”, shaped like a cross, or L-shaped.

In specific implementation, the signals that need to switch layers may be classified into groups of signals that need to switch layers according to an inter-signal spatial distance of the various signals that need to switch layers on the PCB 201 and/or a signal type. Each group of signals that need to switch layers corresponds to a PCB signal via structure. For example, if a minimum distance between surface-layer routes of two signals that need to switch layers is less than or equal to a first preset distance, it is considered that the two signals that need to switch layers meet a requirement of being classified into the same group of signals that need to switch layers. Or, if two signals that need to switch layers are of the same type, for example, if the two signals are differential signals, the two signals may be classified into the same group of signals that need to switch layers. One or two of the inter-signal spatial distance and the signal type may be considered. Other factors may also be considered, such as grouping signals that need to switch layers with the same (the same signal starting layer and the same signal destination layer) or similar layer switching requirements into the group of signals that need to switch layers.

During or after the classification of the signals that need to switch layers, according to the layout of routes on layer surfaces of the PCB 201, the shape of the PCB signal via structure that meets the layer switching requirements of the signals that need to switch layers and does not affect other routes is designed, and its cross section may be shaped like a Chinese character “-”, shaped like a cross, L-shaped, or in any other shapes.

In some embodiments of the present application, the above embodiments explain the various embodiments corresponding to the PCB signal via structure in detail. Based on this, the present application further discloses a PCB corresponding to the PCB signal via structure. The PCB may include the PCB signal via structure provided in any of the above embodiments.

The specific implementation of the PCB provided in the embodiments of the present application can be found in the description of the PCB signal via structure.

Corresponding to the PCB signal via structure, the present application further discloses a determination method, determination apparatus, and determination device for a PCB signal via structure, and a computer-readable storage medium.

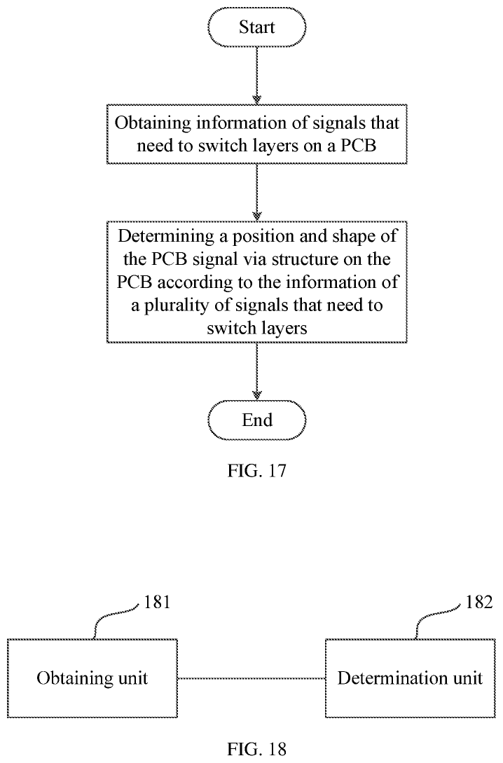

In some embodiments of the present application, FIG. 17 is a flowchart of a determination method for a PCB signal via structure according to the embodiments of the present application.

As shown in FIG. 17, the determination method for the PCB signal via structure provided by the embodiments of the present application includes:

S101: Obtaining information of signals that need to switch layers on a PCB. The information of the signals that need to switch layers at least includes a signal starting layer of the signals that need to switch layers and a signal destination layer of the signals that need to switch layers.

S102: Determining a position and shape of the PCB signal via structure on the PCB according to the information of a plurality of signals that need to switch layers,
wherein the PCB signal via structure includes a via structure arranged on the PCB and in-via routes arranged on an inner wall of the via structure; the via structure spans from the signal starting layer of the signals that need to switch layers in the PCB to the signal destination layer of the signals that need to switch layers; the in-via routes are in one-to-one correspondence to the signals that need to switch layers to serve as via links of the signals that need to switch layers; and the various in-via routes are insulated from each other.

In specific implementation, a script can be pre-written to achieve the steps of the determination method for the PCB signal via structure provided by the embodiments of the present application. The script is used for converting an input design requirement into optional information of the PCB signal via structure. Therefore, during the design of the PCB, a PCB designer can output positions and shapes of PCB signal via structures to be selected by inputting the information of the signals that need to switch layers. In a case that the design requirement (including but not limited to the signal starting layer of the signals that need to switch layers and the signal destination layer of the signals that need to switch layers) is met, information of a plurality of PCB signal via structures to be selected can be output for selection.

A simulation model of the PCB signal via structure to be selected may also be automatically generated according to the information of the PCB signal via structure to be selected by calling mapping software and simulation software, whereby the PCB designer can intuitively view the information.

Step S102: Determining a position and shape of the PCB signal via structure on the PCB according to the information of a plurality of signals that need to switch layers, which may specifically include:
classifying the plurality of signals that need to switch layers into a group of signals that need to switch layers according to an inter-signal spatial distance and/or a signal type; and
determining the position and shape of the PCB signal via structure corresponding to the group of signals that need to switch layers according to the information of the various signals that need to switch layers in the group of signals that need to switch layers.

In addition to the signal starting layer of the signals that need to switch layers and the signal destination layers of the signals that need to switch layers, the information may also include a spatial distance between the signals that need to switch layers, a signal type of the signals that need to switch layers, and a route layout of the PCB, whereby the position and shape of the PCB signal via structure are determined comprehensively.

In addition, a via structure at least includes at least one of a plating through hole structure, a blind via hole structure, and a buried via hole structure; the plating through hole structure penetrates through the PCB; the blind via hole structure spans from a surface layer to an inner layer of the PCB and does not penetrate through the PCB; and the buried via hole structure spans from an inner layer of the PCB, and plating flattening treatment is performed on one side of a surface close to the PCB.

If each signal that needs to switch layers is a differential signal; a via structure at least includes at least one of a first via structure and a second via structure; and a pair of differential signals in the first via structure is only provided with ground signals on two sides; and a pair of differential signals in the second via structure is provided with the ground signals on two sides and opposite sides.

In the determination method for the PCB signal via structure provided by the embodiments of the present application, via links of a plurality of signals that need to switch layers may be finally arranged in the same PCB signal via structure, including one or two of the first via structure and the second via structure, or including at least one of the plating through hole structure, the blind via hole structure, and the buried via hole structure.

The embodiment of the determination method for the PCB signal via structure corresponds to the embodiment of the PCB signal via structure, whereby for the embodiment of the determination method for the PCB signal via structure, refer to the description of the embodiment of the PCB signal via structure. It will not be elaborated here.

In some embodiments of the present application, FIG. 18 is a schematic structural diagram of a determination apparatus for a PCB signal via structure according to the embodiments of the present application.

As shown in FIG. 18, the determination apparatus for the PCB signal via structure provided by the embodiments of the present application includes:
an obtaining unit 181, configured for obtaining information of signals that need to switch layers on a PCB, wherein the information of the signals that need to switch layers at least includes a signal starting layer of the signals that need to switch layers and a signal destination layer of the signals that need to switch layers; and
a determination unit 182, configured for determining a position and shape of the PCB signal via structure on the PCB according to the information of a plurality of signals that need to switch layers,
wherein the PCB signal via structure includes a via structure arranged on the PCB and in-via routes arranged on an inner wall of the via structure; the via structure spans from the signal starting layer of the signals that need to switch layers in the PCB to the signal destination layer of the signals that need to switch layers; the in-via routes are in one-to-one correspondence to the signals that need to switch layers to serve as via links of the signals that need to switch layers; and the various in-via routes are insulated from each other.

The embodiment of the determination apparatus for the PCB signal via structure corresponds to the embodiment of the PCB signal via structure and the embodiment of the determination method for the PCB signal via structure, whereby for the embodiment of the determination apparatus for the PCB signal via structure, refer to the descriptions of the embodiment of the PCB signal via structure and the embodiment of the determination method for the PCB signal via structure. It will not be elaborated here.

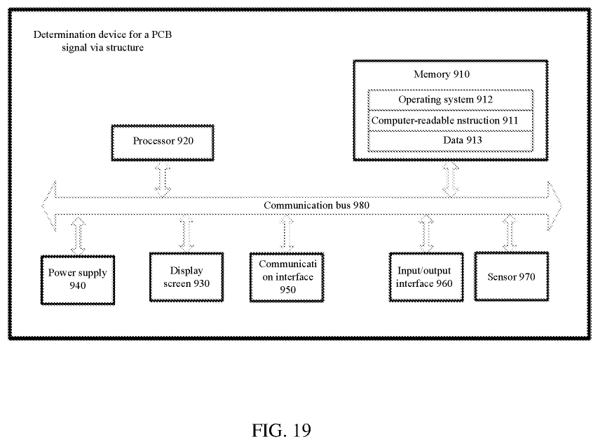

In some embodiments of the present application, FIG. 19 is a schematic structural diagram of a determination device for a PCB signal via structure according to the embodiments of the present application.

As shown in FIG. 19, the determination device for the PCB signal via structure provided by the embodiments of the present application includes:
a memory 910, configured for storing computer-readable instructions 911; and
one or more processors 920, configured for executing the computer-readable instructions 911, wherein the computer-readable instructions 911, when executed by the one or more processors 920, implement the steps of the determination method for the PCB signal via structure according to any one of the embodiments described above.

The processor 920 may include one or more processing cores, such as a 3-core processor and an 8-core processor. The processor 920 may be implemented in at least one hardware form of a digital signal processor (DSP), a field-programmable gate array (FPGA), and a programmable logic array (PLA). The processor 920 may also include a main processor and a coprocessor. The main processor is a processor configured for processing data in an awake state, and is also referred to as a CPU. The coprocessor is a low-power processor configured for processing data in a standby state. In some embodiments, the processor 920 may be integrated with a graphics processing unit (GPU). The GPU is configured for rendering and drawing content that needs to be displayed on a display screen. In some embodiments, the processor 920 may further include an artificial intelligence (AI) processor. The AI processor is configured for processing computing operations related to machine learning.

The memory 910 may include one or more computer-readable storage media. The computer-readable storage medium may be non-transitory. The memory 910 may also include high-speed random access memory and a non-volatile memory, such as one or more magnetic storage devices and flash storage devices. In this embodiment, the memory 910 is at least configured for storing the following computer-readable instructions 911, wherein after being loaded and executed by the processor 920, the computer-readable instructions 911 can implement the relevant steps in the determination method for the PCB signal via structure disclosed in any one of the foregoing embodiments. In addition, resources stored in the memory 910 may also include an operating system 912 and data 913, and a storage mode may be temporary storage or permanent storage. The operating system 912 can be Windows. The data 913 may include but not limited to data involved in the method described above.

In some embodiments, the determination device for the PCB signal via structure may further include a display screen 930, a power supply 940, a communication interface 950, an input/output interface 960, a sensor 970, and a communication bus 980.

A person skilled in the art may understand that the structures shown in FIG. 9 impose no limitation on the determination device for the PCB signal via structure, and may include more or fewer components than those shown in the figure.

The determination device for the PCB signal via structure provided by the embodiments of the present application includes the memory and the processor. The processor can implement the determination method for the PCB signal via structure as described above when running a program stored in the memory. The effects are the same as above.

In some embodiments of the present application, it should be noted that the above-described apparatus and device embodiments are merely illustrative. For example, the division of the modules is only one type of logical functional division, and other divisions are achieved in practice. For another example, multiple modules or components can be combined or integrated into another system, or some features can be omitted, or not executed. In addition, the shown or discussed mutual coupling or direct coupling or communication connection is an indirect coupling or communication connection through some interfaces, apparatuses or modules, and is in an electrical, mechanical or another form. The modules described as separate parts may or may not be physically separate, and parts displayed as modules may or may not be physical modules, may be located in one position, or may be distributed on a plurality of network modules. Some or all of the modules are selected according to actual needs to achieve the objective of the solution of this embodiment.

In addition, functional modules in embodiments of the present application may be integrated into one processing module, or each of the modules may exist alone physically, or two or more modules are integrated into one module. The integrated modules mentioned above can be implemented in both a hardware form and a software functional module form.

When the integrated module is implemented in the form of a software functional module and sold or used as an independent product, the integrated module may be stored in a computer-readable storage medium. Based on this understanding, the technical solutions of the present application essentially, or the part that contributes to the prior art, or all or some of the technical solutions, can be reflected in the form of a software product. The computer software product is stored in a storage medium to execute all or some of the steps of the methods in the various embodiments of the present application.

Based on this, the embodiments of the present application further provide one or more non-volatile computer-readable storage media storing computer-readable instructions. The computer-readable storage media store computer-readable instructions. The computer-readable instructions, when executed by one or more processors, implement the steps of the determination method for the PCB signal via structure.

The computer-readable storage media include: various media that can store program codes, such as a USB flash drive, a mobile hard disk drive, a Read-Only Memory (ROM), a Random Access Memory (RAM), a magnetic disk, and a compact disc.

The computer-readable instructions included in the computer-readable storage media provided in this embodiment can implement the steps of the determination method for the PCB signal via structure as described above when executed by the processor. The effects are the same as above.

The PCB signal via structure and the determination method, determination apparatus, and determination device therefor, and the computer-readable storage medium are described in detail above. The various embodiments in this specification are described in a progressive manner, and each embodiment focuses on differences from other embodiments. The same and similar parts between all the embodiments can be referred to each other. Since the method, the apparatus, the device, and the computer-readable storage medium disclosed in the embodiments correspond to the PCB signal via structure disclosed in the embodiments, they are described simply, and related parts refer to some of the explanations of the PCB signal via structure. It should be pointed out that a person of ordinary skill in the art can also make several improvements and modifications to the present application without departing from the principles of the present application, and these improvements and modifications also fall within the scope of protection of the claims of the present application.

It should be noted that in this specification, relationship terms such as first and second are used only to distinguish one entity or operation from another entity or operation without necessarily requiring or implying any actual such relationship or order between these entities or operations. Furthermore, the terms “includes”, “including”, or any other variation thereof, are intended to encompass a non-exclusive inclusion, such that a process, method, article, or device that includes a list of elements does not include only those elements but may include other elements not explicitly listed or inherent to such process, method, article, or device. Without further limitation, an element defined by the phrase “including a/an ... ” does not exclude the presence of another identical elements in the process, method, article or device that includes the element.

1. A printed circuit board (PCB) signal via structure, comprising a via structure arranged on a PCB and in-via routes arranged on an inner wall of the via structure,
wherein the via structure spans from a signal starting layer of signals that need to switch layers in the PCB to a signal destination layer of the signals that need to switch layers; the in-via routes are in one-to-one correspondence to the signals that need to switch layers to serve as via links of the signals that need to switch layers; and the in-via routes are insulated from each other.

2. The PCB signal via structure according to claim 1, wherein each of the in-via routes is obtained by performing groove milling on a copper surface according to a line width of each of the signals that need to switch layers and a line distance of each of the signals that need to switch layers after the via structure is obtained from the PCB and the inner wall of the via structure is electroplated with the copper surface that has a same thickness as a layer surface of the PCB.

3. The PCB signal via structure according to claim 1, wherein the via structure comprises a plating through hole structure; and
the plating through hole structure penetrates through the PCB.

4. The PCB signal via structure according to claim 1, wherein the via structure comprises a blind via hole structure; and
the blind via hole structure spans from a surface layer to an inner layer of the PCB and does not penetrate through the PCB.

5. The PCB signal via structure according to claim 1, wherein the via structure comprises a buried via hole structure; and
the buried via hole structure spans from an inner layer of the PCB, and plating flattening treatment is performed on one side closed to a surface of the PCB.

6. The PCB signal via structure according to claim 1, wherein a cross section of the via structure is shaped like a character “-”.

7. The PCB signal via structure according to claim 1, wherein a cross section of the via structure is a cross.

8. The PCB signal via structure according to claim 1, wherein a cross section of the via structure is L-shaped.

9. The PCB signal via structure according to claim 1, wherein each of the signals that need to switch layers is a differential signal;
the via structure at least comprises a first via structure; and
a pair of differential signals in the first via structure is only provided with ground signals on two sides of the first via structure.

10. The PCB signal via structure according to claim 1, wherein each of the signals that need to switch layers is a differential signal;
the via structure at least comprises a second via structure; and
a pair of differential signals in the second via structure is only provided with ground signals on two, opposite sides of the second via structure.

11. A printed circuit board (PCB), comprising a PCB signal via structure, wherein the PCB signal via structure comprises a via structure arranged on the PCB and in-via routes arranged on an inner wall of the via structure, wherein the via structure spans from a signal starting layer of signals that need to switch layers in the PCB to a signal destination layer of the signals that need to switch layers; the in-via routes are in one-to-one correspondence to the signals that need to switch layers to serve as via links of the signals that need to switch layers; and the in-via routes are insulated from each other.

12.-20. (canceled)

21. The PCB signal via structure according to claim 1, wherein a distance between the in-via routes is not less than a distance between a surface-layer route of the signals that need to switch layers.

22. The PCB signal via structure according to claim 21, wherein the distance between the in-via routes is consistent with the distance between the surface-layer route.

23. The PCB signal via structure according to claim 1, wherein the via structure is filled with an insulation material.

24. The PCB signal via structure according to claim 1, wherein the via structure comprises a plating through hole structure, a blind via hole structure, or a buried via hole structure according to layer switching requirements of the signals that need to switch layers.

25. The PCB signal via structure according to claim 1, wherein a depth of the signals that need to switch layers is a thickness of the PCB.

26. The PCB signal via structure according to claim 1, wherein an inner wall of the via structure is electroplated with a copper surface and a thickness of the copper surface is the same as a thickness of an inner-layer copper foil of the PCB.

27. The PCB signal via structure according to claim 1, wherein each of the signals that need to switch layers comprises two differential signals with different signal shielding requirements, and the via structure at least comprises a first via structure and a second via structure;
wherein a pair of differential signals in the first via structure is only provided with ground signals on two sides of the first via structure, and a pair of differential signals in the second via structure is only provided with ground signals on two, opposite sides of the second via structure.

28. The PCB signal via structure according to claim 1, wherein each of the signals that need to switch layers comprises two pairs of differential signals and two sides of the via structure set round signals and the in-via routes at opposite side corners of the via structure set ground signals.

29. An electronic device, comprising a printed circuit board (PCB), wherein the PCB comprises a PCB signal via structure, the PCB signal via structure comprises a via structure arranged on the PCB and in-via routes arranged on an inner wall of the via structure, the via structure spans from a signal starting layer of signals that need to switch layers in the PCB to a signal destination layer of the signals that need to switch layers; the in-via routes are in one-to-one correspondence to the signals that need to switch layers to serve as via links of the signals that need to switch layers; and the in-via routes are insulated from each other.
